(19) United States
(12) Patent Application Publication
(10) Pub. No.: US 2015/0214253 A1
(43) Pub. Date: Jul. 30, 2015

(54) ARRAY SUBSTRATE, MANUFACTURING METHOD THEREOF AND DISPLAY DEVICE

(71) Applicants: HEFEI BOE OPTOELECTRONICS TECHNOLOGY CO., LTD., Anhui (CN); BOE TECHNOLOGY GROUP CO., LTD., Beijing (CN)

(72) Inventors: Xiangyang Xu, Beijing (CN); Minsu Kim, Beijing (CN); Kai Wang, Beijing (CN)

(73) Assignee: HEFEI BOE OPTOELECTRONICS TECHNOLOGY CO. LTD, Hefel, Anhui (CN)

(21) Appl. No.: 14/355,463

(22) PCT Filed: Dec. 11, 2013
(86) PCT No.: PCT/CN2013/089144

§ 371 Date: Apr. 30, 2014

(30) Foreign Application Priority Data
May 23, 2013 (CN) 201310195242.6

(51) Int. Cl. H01L 27/12

(52) U.S. Cl. CPC H01L 27/1248; H01L 27/1225; H01L 27/1262; H01L 27/124

(57) ABSTRACT

An array substrate, a manufacturing method thereof and a display device are provided, relate to the display technical field, and are used for the manufacturing of the display device, which can reduce a parasitic capacitance between a gate and a drain, so as to reduce power consumption of the array substrate and increase the picture displaying quality. The array substrate includes: a base substrate; a patterned gate metal layer, a gate insulation layer, a patterned semiconductor active layer, a patterned source and drain metal layer, and a pixel electrode, disposed on the base substrate; and an organic transparent insulation layer, disposed between the patterned gate metal layer and the pixel electrode.

### TECHNICAL FIELD

Embodiments of the present invention relate to an array substrate, and manufacturing method thereof and a display device.

### BACKGROUND

With the continual development of a thin film transistor liquid crystal display (TFT-LCD), the picture quality is getting more and more attention.

As to a current LCD, a pixel electrode is charged mainly by turning on and turning off a thin film transistor disposed on an array substrate, so as to achieve a rotation of liquid crystal. As to other type display panel, such as an electroluminescence display panel, it also needs a thin film transistor to drive a pixel to perform displaying. However, since there exists a parasitic capacitance C_{gd} between a gate and a drain of a TFT, at the moment of turning on the TFT, the parasitic capacitance C_{gd} will pull down a pixel voltage, so that it cause power consumption of the array substrate to increase, and the picture quality is also influenced.

### SUMMARY

Embodiments of the present invention provide an array substrate, and manufacturing method thereof and a display device, which can reduce a parasitic capacitance between a gate and a drain, so as to reduce power consumption of the array substrate and increase the picture displaying quality.

On one aspect, an embodiment of the present invention provides an array substrate, comprising: a base substrate; a patterned gate metal layer, a gate insulation layer, a patterned semiconductor active layer, a source and drain metal layer, and a pixel electrode, disposed on the base substrate; and an organic transparent insulation layer, disposed between the patterned gate metal layer and the pixel electrode.

On another aspect, an embodiment of the present invention provides a display device, comprising: the above array substrate; and a color filter substrate, cell-assembled with the array substrate.

On another aspect, an embodiment of the present invention provides a manufacturing method of an array substrate, the method comprising: preparing a base substrate; forming a patterned gate metal layer, a gate insulation layer, a patterned semiconductor active layer, a patterned source and drain metal layer, and a pixel electrode on the base substrate, wherein the method further comprises: forming an organic transparent insulation layer between the patterned gate metal layer and the pixel electrode, wherein the patterned gate metal layer comprises a gate and a gate line, and the patterned source and drain metal layer comprises a source and a drain.

### BRIEF DESCRIPTION OF DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIGS. 1-7 are schematic views showing an array substrate obtained after various steps during manufacturing the array substrate according to a first embodiment of the present invention;

FIGS. 8-9 are schematic views showing an array substrate obtained after various steps during manufacturing the array substrate according to a second embodiment of the present invention; and

FIGS. 10-12 are schematic views showing an array substrate obtained after various steps during manufacturing the array substrate according to a third embodiment of the present invention.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

An embodiment of the present invention provides a manufacturing method of an array substrate, the method comprising: forming a patterned gate metal layer, a gate insulation layer, a patterned semiconductor active layer, a patterned source and drain metal layer, and a pixel electrode on a base substrate; and further comprising: forming an organic transparent insulation layer between the patterned gate metal layer and the pixel electrode.

Herein, in an embodiment of the present invention, the patterned source and drain metal layer comprises a source and a drain, and the patterned gate metal layer comprises a gate and a gate line.

Material of the organic transparent insulation layer may be one type of photoresist (PR) material, and the material of the organic transparent insulation layer described here may be organic transparent insulating material with high transmittance and in this way, it may avoid the organic transparent insulation layer influence the transmittance of the display panel.

Exemplarily, a thickness of the organic transparent insulation layer is 2000 Å˜5000 Å.

According to an equation of parallel plate capacitance C,

$$i . e . C ∝ \frac{ɛ S}{d} ,$$

wherein ∈ is a dielectric constant, S is an overlapping area of the parallel plate, and d is a distance of the parallel plates. It can be known from the equation that a capacitance is in proportion with the overlapping area of the parallel plates, is in proportion with the dielectric constant of the dielectric, and is in reverse proportion with the distance of the parallel plates. It can be seen from this, when the organic transparent insulation layer is formed between the gate metal layer and the pixel electrode in the embodiment of the present invention, it increases the distance between the gate and the pixel electrode, and since the pixel electrode is connected with the drain, the parasitic capacitance C_{gd} between the gate and the drain can be reduced, and thus, power consumption of the array substrate can be reduced, and the picture displaying quality can be improved.

Considering when the organic transparent insulation layer is formed below the patterned source and drain metal layer, that is, the organic transparent insulation layer is first formed and then the patterned source and drain metal layer is formed, due to limitations of process, it may cause influence on patterning of the source and drain metal layer, thus, exemplarily, the organic transparent insulation layer is formed between the patterned source and drain metal layer and the pixel electrode; and the pixel electrode is connected with the drain by a through hole exposing the drain.

It is to be noted here that, “the pixel electrode is connected with the drain by the through hole exposing the drain” refers to: in the embodiment of the present invention, first forming the patterned source and drain metal layer comprising the drain, and then forming other layers on the patterned source and drain metal layer, and subsequently forming the pixel electrode, wherein with respecting to the other layers on the source and drain metal layer, it needs to form the through hole exposing the drain, so that the subsequently formed pixel electrode is connected with the drain by the through hole exposing the drain.

Exemplarily, oxide semiconductor is widely used in the liquid crystal display field due to its characteristics such as high electron mobility, excellent uniformity and so on, and thus, when the semiconductor active layer is a oxide semiconductor active layer, the method further comprises: forming an etching blocking layer on a side of the semiconductor active layer opposite to the base substrate.

Herein, material of the oxide semiconductor active layer may be ZnO, InZnO, ZnSnO, GaInZnO, ZrInZnO or the like.

Since the material of the oxide semiconductor active layer is easy to react with the oxygen in the air or water when it is exposed outside so as to cause the property of the thin film transistor change, thus, in the embodiment of the present invention, for example, the etching blocking layer is formed above the oxide semiconductor active layer, which is used to avoid influencing on the oxide semiconductor active layer when etching a metal layer on the oxide semiconductor active layer in the subsequent process, and can also avoid the oxide semiconductor active layer being exposed to the outside and reacting with the oxygen in the air or water to thus cause the property of the thin film transistor change.

It is to be noted here that, in the embodiment of the present invention, “forming the etching blocking layer on a side of the semiconductor active layer opposite to the base substrate” particularly refers to: first forming the oxide semiconductor active layer, and then forming the etching blocking layer, and other cases are in the same way, and it is not repeated here.

A detailed embodiment is provided below, to explain a manufacturing process of the above array substrate in detail.

### A First Embodiment

The present embodiment provides a manufacturing method of an array substrate, comprising the following steps:

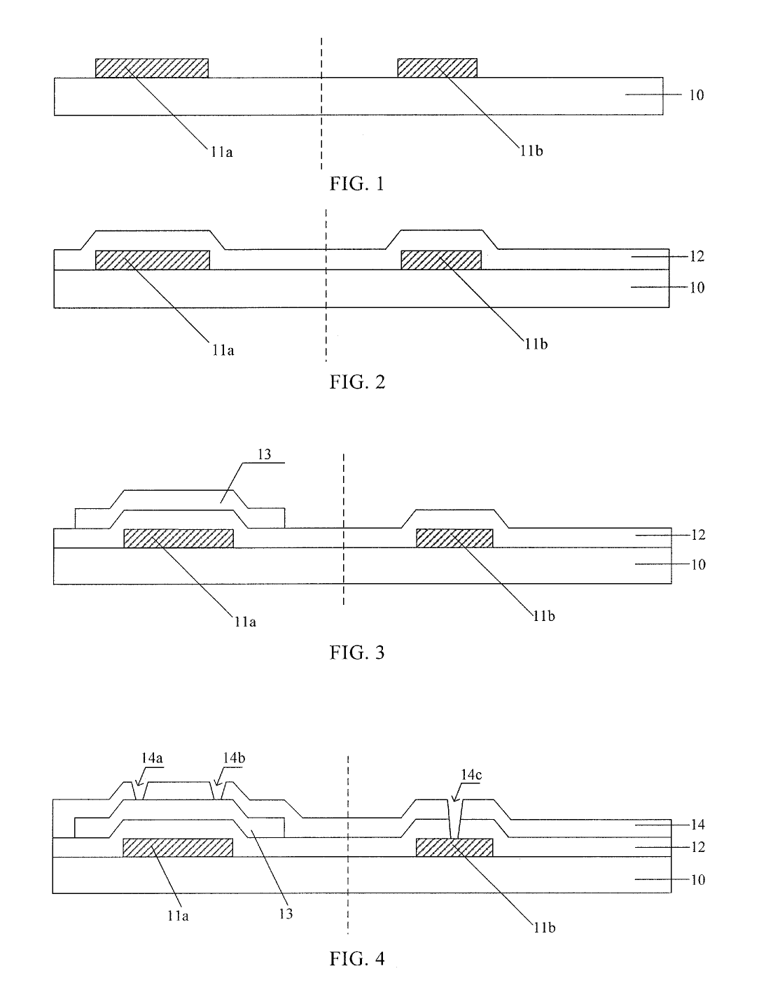

S101: fabricating a metal thin film on a base substrate 10, and forming a patterned gate metal layer as shown in FIG. 1 by one patterning process, wherein the patterned gate metal layer comprises a gate 11a, a gate line (not shown) and a gate leading wire 11b.

Exemplarily, a metal thin film having a thickness of 2000 Å˜5000 Å is fabricated on the base substrate 10 by using a magnetron sputtering method. The metal thin film may generally be made of Mo, Al, AlNi alloy, MoW alloy, Cr, Cu or other metals, and may also use a combination structure of the above described several thin films. Subsequently, the patterned gate metal layer comprising the gate 11a, the gate line (not shown) and the gate leading wire 11b is formed on a certain region of the base substrate by exposing, developing, etching, removing and so on using a mask.

It is to be noted here that, “thin film” refers to a layer of thin film fabricated on a base substrate by depositing or other process with a certain kind of material. If the “thin film” does not need to be patterned in the whole manufacturing process, the “thin film” may also be called as a “layer”; if the “thin film” still needs to be patterned in the whole manufacturing process, it can be called as a “thin film” before the patterning process, and called as a “layer” after the patterning process.

Herein, the patterning process generally comprises: coating a photoresist on the thin film, exposing the photoresist by using a mask, then removing the photoresist needed to be removed by using a developing solution, then etching a portion of the thin film not covered by the photoresist, and finally removing the remaining photoresist.

S102: fabricating an insulating thin film on the substrate obtained after the step S101, to form a gate insulation layer 12 as shown in FIG. 2.

Exemplarily, an insulating thin film having a thickness of 2000 Å˜5000 Å may be continually deposited on the base substrate by using a chemical vapor deposition method, and material of the insulating thin film is generally silicon nitride, and may also use silicon oxide, silicon oxynitride or the like.

S103: fabricating an oxide semiconductor thin film on the base substrate obtained after the step S102, and forming an oxide semiconductor active layer 13 as shown in FIG. 3 by one patterning process.

Exemplarily, an oxide semiconductor thin film having a thickness of 500 Å˜800 Å may be deposited on the substrate by using a chemical vapor deposition method, and material of the oxide semiconductor active layer may generally be ZnO, InZnO, ZnSnO, GaInZnO, ZrInZnO or the like. Then, the oxide semiconductor active layer 13 is formed on a certain region of the substrate by a patterning process such as exposing, developing, etching, removing and the like using a mask.

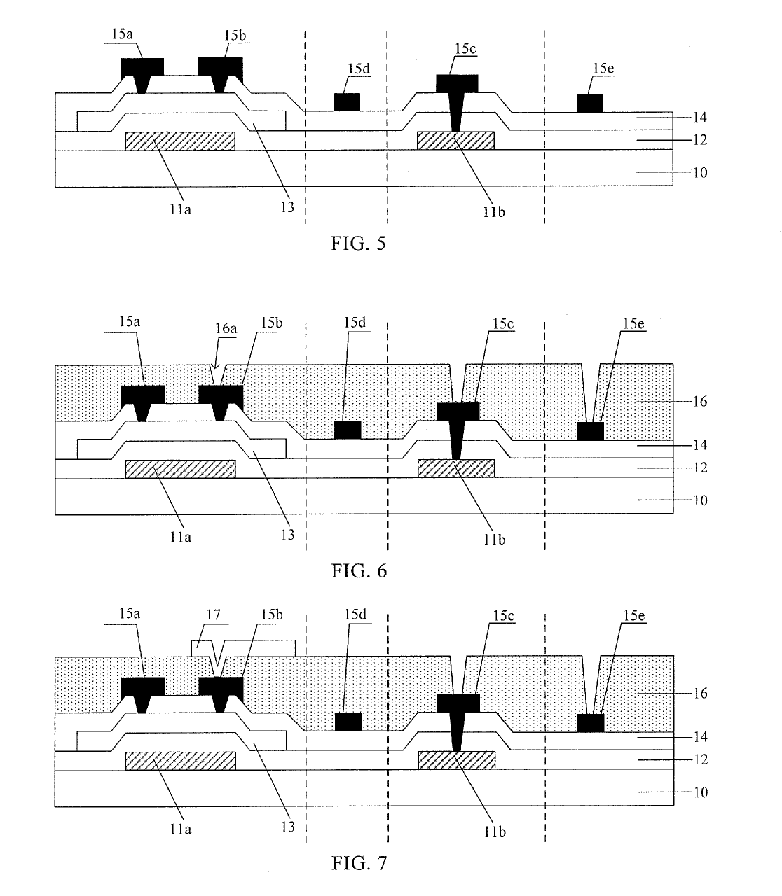

S104: fabricating an inorganic thin film on the substrate obtained after the step S103, and forming an etching blocking layer 14 as shown in FIG. 4 by one patterning process.

Herein, the etching blocking layer comprises a first through hole 14a and a second through hole 14b exposing the oxide semiconductor active layer 13, and a third through hole 14c exposing the gate leading wire 11b.

Exemplarily, an inorganic thin film having a thickness of 500 Å˜2000 Å may be deposited on the substrate, and material of the inorganic thin film may be SiOx, for example. Subsequently, the etching blocking layer 14 is formed on a certain region of the substrate by a patterning process such as exposing, developing, etching, removing and the like using a mask.

In this way, it can avoid influencing on the oxide semiconductor active layer when etching a metal layer on the oxide semiconductor active layer in the subsequent process, and can also avoid the oxide semiconductor active layer being exposed to the outside and reacting with the oxygen in the air or water to thus cause the property of the thin film transistor change.

Here, since there is the gate insulation layer 12 formed above the gate leading wire 11b, and the third through hole 14c exposes the gate leading wire 11b, the gate insulation layer 12 is also etched to form the through hole exposing the gate leading wire 11b while etching the etching blocking layer 14.

S105: fabricating a metal thin film on the substrate obtained after the step S104, and forming the patterned sourced and drain metal layer as shown in FIG. 5 by one patterning process.

Herein, the patterned source and drain metal layer comprises: a source 15a in contact with the oxide semiconductor active layer 13 by the first through hole 14a, a drain 15b in contact with the oxide semiconductor active layer 13 by the second through hole 14b, a metal pattern 15c electrically connected with the gate leading wire 11b by the third through hole 14c, and a data line 15d and a data line leading wire 15e.

Exemplarily, a metal thin film having a thickness of 1000 Å˜6000 Å may be fabricated on the substrate by using a magnetron sputtering method. Subsequently, the patterned source and drain metal layer is formed on the substrate by a patterning process such as exposing, developing, etching, removing and the like using a mask.

S106: fabricating an organic transparent insulation thin film on the substrate obtained after the step S105, and forming the organic transparent insulation layer 16 as shown in FIG. 6 by one patterning process; wherein the organic transparent insulation layer 16 comprises a fourth through hole 16a exposing the drain 15b.

In addition, the organic transparent insulation layer 16 further comprises through holes exposing the metal pattern 15c and the data line leading wire 15e.

Exemplarily, an organic transparent insulation thin film having a thickness of 2000 Å˜5000 Å may be deposited on the substrate, and subsequently, the organic transparent insulation layer 16 is formed on the substrate by a patterning process such as exposing, developing, etching, removing and the like using a mask.

S107: fabricating a transparent conductive thin film on the substrate obtained after the step S106, and forming a pixel electrode 17 as shown in FIG. 7 by one patterning process, wherein the pixel electrode 17 is connected with the drain 15b by the fourth through hole 16a.

Exemplarily, a transparent conductive thin film having a thickness of 100 Å˜1000 Å may be deposited on the substrate by using a chemical vapor deposition method, and material of the transparent conductive thin film may generally be indium tin oxide (ITO) or indium zinc oxide (IZO). Subsequently, the pixel electrode 17 is formed on a certain region of the substrate by a patterning process such as exposing, developing, etching, removing and the like using a mask.

It is to be noted that, the first embodiment of the present invention provides only one exemplary manufacturing method of an array substrate, and the embodiments of the present invention are not limited thereto, and other manufacturing methods of an array substrate can be provided, for example, a manufacturing method of a top gate type array substrate may be used, and no matter which kind of manufacturing method, in the embodiments of the present invention, it only needs to form the organic transparent insulation layer between the source and drain metal layer and the pixel electrode.

In the embodiments of the present invention, since the organic transparent insulation layer is added between the source and drain metal layer and the pixel electrode, it causes a distance between the gate and the pixel electrode to be correspondingly increased, and according to the equation of capacitance, it can thus reduce the parasitic capacitance between the gate and the pixel electrode, and since the pixel electrode is connected with the drain, it can reduce the parasitic capacitance C_{gd} between the gate and the drain, and then reduce the power consumption of the array substrate and improve picture displaying quality.

The array substrate provided by the embodiments of the present invention is suitable for the production of the ADvanced Super Dimension Switch (AD-SDS, abbreviated as ADS) technology type liquid crystal display device. Herein, the core of the AD-SDS technology is described as: an electric field generated by fringes of slit electrodes in the same plane and an electric field generated between the slit electrode layer and a plate electrode layer can constitute a multi-dimension electric field, so as to make liquid crystal molecules oriented in all directions between the slits electrodes and directly above the electrodes inside a liquid crystal cell capable of rotating, thus improving the operating efficiency of liquid crystal and increasing the light transmittance. The ADS technology can improve the displaying quality of a TFT-LCD, and has advantages of high resolution, high transmittance, low power consumption, wide viewing angle, high aperture ratio, low chromatic aberration, no push Mura, etc.

Exemplarily, for the AD-SDS technology type liquid crystal display device, the method according to the first embodiment of the present invention further comprises: forming a passivation layer and a common electrode on the base substrate, and the pixel electrode and the common electrode are respectively formed at two sides of the passivation layer, wherein the pixel electrode is connected with the drain by the through hole exposing the drain.

Alternatively, the pixel electrode is formed between the passivation layer and the organic transparent insulation layer, and the common electrode is formed on a side of the passivation layer opposite to the base substrate; or, the common electrode is formed between the passivation layer and the organic transparent insulation layer, and the pixel electrode is formed on a side of the passivation layer opposite to the base substrate.

The following will give two detailed embodiments, to describe in detail the above manufacturing process of the array substrate suitable for the AD-SDS technology type liquid crystal display device.

### A Second Embodiment

The present embodiment provides a manufacturing method of an array substrate, and on the basis of the steps S101-S107 of the above first embodiment, the method further comprise the following steps:

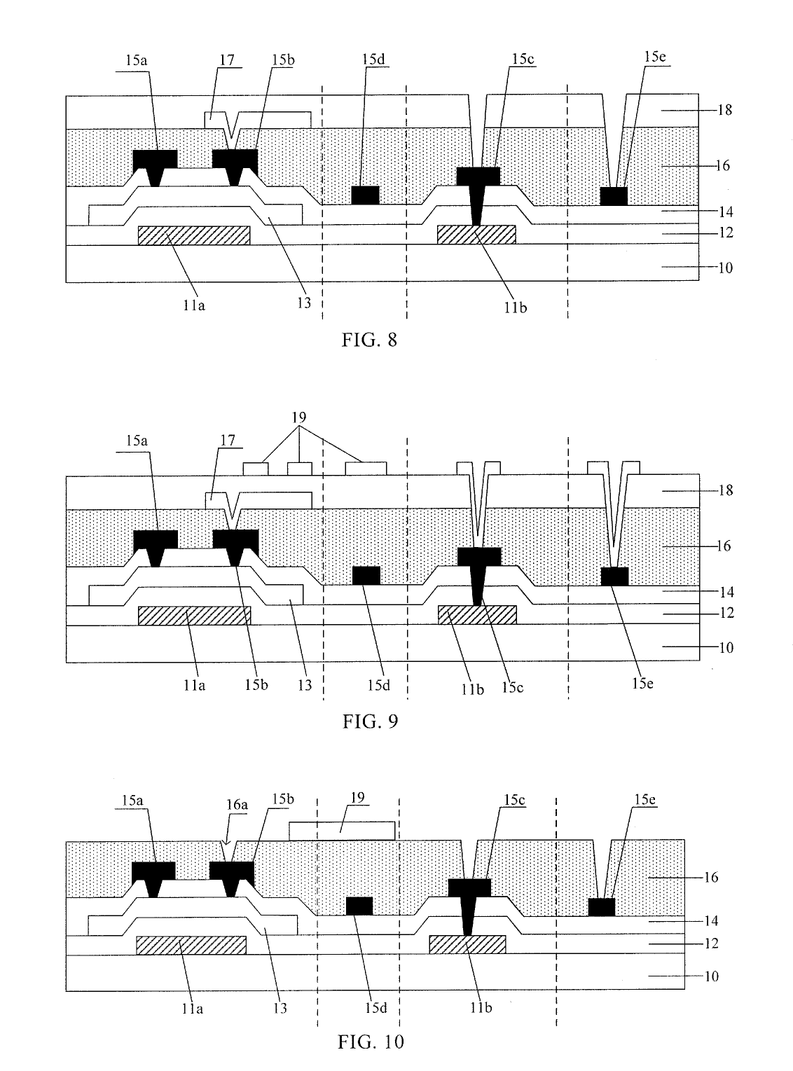

S201: fabricating a passivation layer thin film on the substrate obtained after the above step S107, and forming the passivation layer 18 as shown in FIG. 8 by one patterning process.

Herein, the passivation layer comprises through holes exposing the metal pattern 15c and the data line leading wire 15e.

Exemplarily, a passivation layer thin film having a thickness of 2000 Å˜4000 Å may be coated on the entire substrate, and material of the passivation layer thin film is generally silicon nitride or transparent organic resin material. Subsequently, the passivation layer is formed on the substrate by a patterning process such as exposing, developing, etching, removing and the like using a mask.

S202: fabricating a transparent conductive thin film on the substrate obtained after the step S201, and forming the common electrode 19 as shown in FIG. 9 by one patterning process.

In addition, when forming the common electrode 19, a remaining pattern connected with the metal pattern 15c and the data line leading wire 15e is further formed.

In addition, due to the organic transparent insulation layer 16, it can improve wiring density of the common electrode, and avoid parasitic capacitance generated between the common electrode and the data line.

In the embodiment of the present invention, on one aspect, the AD-SDS technology can improve the picture quality of a TFT-LCD, and have advantages such as high resolution, high transmittance, low power consumption, wide viewing angle, high aperture ratio, low chromatic aberration, no push Mura and so on; on the other aspect, since the organic transparent insulation layer is added between the source and drain metal layer and the pixel electrode, it can reduce the parasitic capacitance C_{gd} between the gate and the drain, and thus reduce the power consumption of the array substrate and improve the picture displaying quality.

### A Third Embodiment

The present embodiment provides a manufacturing method of an array substrate, and the method comprises the steps S101-S106 of the above described first embodiment as the basis, and further comprises the following steps:

S301: fabricating a transparent conductive thin film on the substrate obtained after the above described step S106, and forming the common electrode 19 as shown in FIG. 10 by one patterning process.

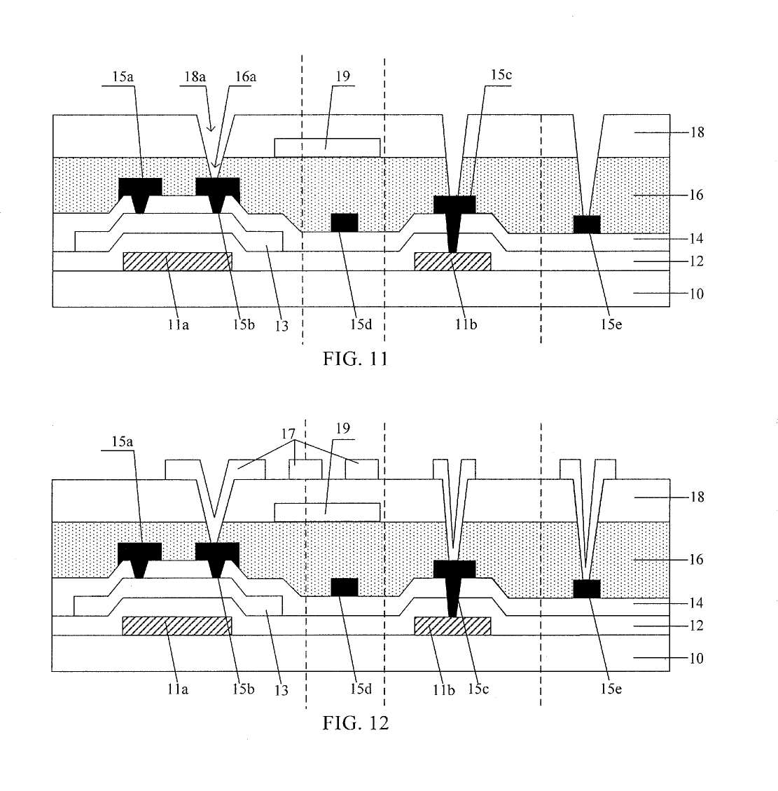

S302: fabricating a passivation layer thin film on the substrate obtained after the step S301, and forming the passivation layer 18 as shown in FIG. 11 by one patterning process, wherein the passivation layer 18 comprises a fifth through hole 18a exposing the drain 15b.

In addition, the passivation layer 18 further comprise through holes exposing the metal pattern 15c and the data line leading wire 15e.

S303: fabricating a transparent conductive thin film on the substrate obtained after the step S302, and forming the pixel electrode 17 as shown in FIG. 12 by one patterning process, wherein the pixel electrode 17 is connected with the drain 15b by the fourth through hole 16a and the fifth through hole 18a.

In addition, when forming the pixel electrode 17, the remaining pattern at the same layer of the first electrode 17 is further formed, and the remaining pattern is electrically connected with the metal pattern and the data line leading wire by the through holes exposing the metal pattern 15c and the data line leading wire 15e.

It can be seen from the above description that, the manufacturing method of the array substrate provided by the third embodiment is different from the second embodiment in that: a forming order of the pixel electrode and the common electrode. It can be seen form this that, no matter first forming the pixel electrode or first forming the common electrode, as long as the organic transparent insulation layer is formed between the pixel electrode layer and the source and drain metal layer, it can reduce the parasitic capacitance C_{gd} between the gate and the drain, so that it can reduce the power consumption of the array substrate and improve the picture displaying quality.

In addition, the embodiment of the present invention further provides an array substrate, and referring to FIGS. 8, 11 and 12, the array substrate comprises: a base substrate 10; a patterned gate metal layer, a gate insulation layer 12, a patterned semiconductor active layer 13, a source and drain metal layer, and a pixel electrode, disposed on the base substrate, wherein an organic transparent insulation layer 16 is disposed between the patterned gate metal layer and the pixel electrode 17.

Herein, the patterned gate metal layer comprises a gate 11a, and further comprises a gate line, a gate line leading wire 11b, and so on; the patterned source and drain metal layer comprises a source 15a and a drain 15b, and further comprises a data line 15d, a data line leading wire 15e, and so on.

Material of the organic transparent insulation layer may be one type of photoresist (PR) material, and the material of the organic transparent insulation layer here described may be high transmittance organic transparent insulation material, and in this way, it can avoid the organic transparent insulation layer have an influence on the transmittance of the display panel.

Exemplarily, a thickness of the organic transparent insulation layer may be 2000 Å˜5000 Å.

According to an equation of parallel plate capacitance C,

$$i . e . C ∝ \frac{ɛ S}{d} ,$$

wherein ∈ is a dielectric constant. S is an area of the parallel plate, and d is a distance of the parallel plates. It can be known from the equation that a capacitance is in proportion with an overlapping area of the parallel plates, is in proportion with the dielectric constant of the dielectric, and is in reverse proportion with the distance of the parallel plates. It can be seen from this, when the organic transparent insulation layer is formed between the gate metal layer and the pixel electrode in the embodiment of the present invention, it increases the distance between the gate and the pixel electrode, and since the pixel electrode is connected with the drain, the parasitic capacitance C_{gd} between the gate and the drain can be reduced, and thus, power consumption of the array substrate can be reduced, and the picture displaying quality can be improved.

Considering when the organic transparent insulation layer 16 is formed below the source and drain metal layer, that is, the organic transparent insulation layer is first formed and then the source and drain metal layer is formed, due to limitations of process, it may cause influence on patterning of the source and drain metal layer, thus, exemplarily, the organic transparent insulation layer 16 is formed between the source and drain metal layer and the pixel electrode 17; and the pixel electrode 17 is connected with the drain 15b by a through hole exposing the drain 15b.

Exemplarily, oxide semiconductor is widely used in the liquid crystal display field due to its characteristics such as high electron mobility, excellent uniformity and so on, and thus, as shown in FIGS. 8, 11 and 12, when the semiconductor active layer 13 is a oxide semiconductor active layer, the array substrate further comprises: an etching blocking layer 14, disposed on a side of the semiconductor active layer opposite to the base substrate.

Herein, material of the oxide semiconductor active layer may be ZnO, InZnO, ZnSnO, GaInZnO, ZrInZnO or the like.

Since the material of the oxide semiconductor active layer 13 is easy to react with the oxygen in the air or water when it is exposed outside so as to cause the property of the thin film transistor change, thus, in the embodiment of the present invention, for example, the etching blocking layer is formed on a side of the semiconductor active layer 13 opposite to the base substrate, which is used to avoid influencing on the oxide semiconductor active layer when etching a metal layer on the oxide semiconductor active layer in the subsequent process, and can also avoid the oxide semiconductor active layer being exposed to the outside and reacting with the oxygen in the air or water to thus cause the property of the thin film transistor change.

The array substrate provided by the embodiment of the present invention may be applied to the AD-SDS technology type display device, so that the display device has advantages such as high resolution, high transmittance, low power consumption, wide viewing angle, high aperture ratio, low chromatic aberration, no push Mura and so on.

Thus, exemplarily, as shown in FIGS. 11 and 12, the array substrate further comprises: a passivation layer 18 and a common electrode 19, the pixel electrode 17 and the common electrode 19 are respectively disposed at two sides of the passivation layer 18; the pixel electrode 17 is connected with the drain 15b by the through hole disposed above the drain 15b.

Alternatively, as shown in FIG. 9, the pixel electrode 17 is formed between the passivation layer 18 and the organic transparent insulation layer 16, and the common electrode 19 is formed on a side of the passivation layer 18 opposite to the base substrate; or, as shown in FIG. 12, the common electrode 19 is disposed between the passivation layer 18 and the organic transparent insulation layer 16, and the pixel electrode 17 is disposed on a side of the passivation layer opposite to the base substrate.

An embodiment of the present invention provides an array substrate, comprising: a patterned gate metal layer, a gate insulation layer, a patterned semiconductor active layer, a source and drain metal layer, and a pixel electrode, disposed on the base substrate; and further comprising an organic transparent insulation layer disposed between the gate metal layer and the pixel electrode; since the organic transparent insulation layer is added between the source and drain metal layer and the pixel electrode, a distance between a gate and the pixel electrode is correspondingly increased, and since the pixel electrode is connected with the drain, it can thus reduce the parasitic capacitance C_{gd} between the gate and the drain, so that it can reduce the power consumption of the array substrate and improve picture displaying quality.

An embodiment of the present invention further provides a display device, comprising a color filter substrate and an array substrate cell-assembled, wherein the array substrate may be any one of the above array substrates. The display device may be a liquid crystal display, a liquid crystal television, a digital camera, a mobile phone, a tablet PC, and products or components having displaying function.

The embodiment of the invention being thus described, it will be obvious that the same may be varied in many ways. Such variations are not to be regarded as a departure from the spirit and scope of the invention, and all such modifications as would be obvious to those skilled in the art are intended to be included within the scope of the following claims.

1. An array substrate, comprising:
a base substrate;
a patterned gate metal layer, a gate insulation layer, a patterned semiconductor active layer, a patterned source and drain metal layer, and a pixel electrode, disposed on the base substrate; and
an organic transparent insulation layer, disposed between the patterned gate metal layer and the pixel electrode.

2. The array substrate according to claim 1, wherein the patterned gate metal layer comprises a gate and a gate line, and the patterned source and drain metal layer comprises a source and a drain.

3. The array substrate according to claim 2, wherein
the pixel electrode is connected with the drain by a through hole exposing the drain.

4. The array substrate according to claim 2, wherein the array substrate further comprises a passivation layer and a common electrode, wherein the pixel electrode and the common electrode are respectively disposed at two sides of the passivation layer;
the pixel electrode is connected with the drain by the through hole exposing the drain.

5. The array substrate according to claim 4, wherein the pixel electrode is disposed between the passivation layer and the organic transparent insulation layer, and the common electrode is disposed on a side of the passivation layer opposite to the base substrate; or
the common electrode is disposed between the passivation layer and the organic transparent insulation layer, and the pixel electrode is disposed on a side of the passivation layer opposite to the base substrate.

6. The array substrate according to claim 2, further comprising: an etching blocking layer, formed on a side of the semiconductor active layer opposite to the base substrate, and the semiconductor active layer is an oxide semiconductor active layer.

7. The array substrate according to claim 2, wherein a thickness of the organic transparent insulation layer is 2000 Å˜5000 Å.

8. The array substrate according to claim 6, wherein material of the oxide semiconductor active layer is ZnO, InZnO, ZnSnO, GaInZnO or ZrInZnO.

9. The array substrate according to claim 2, wherein the array substrate is a top-gate type array substrate or a bottom-gate type array substrate.

10. A display device, comprising:
the array substrate according to claim 1; and
a color filter substrate, cell-assembled with the array substrate.

11. A manufacturing method of an array substrate, the method comprising:
providing a base substrate;
forming a patterned gate metal layer, a gate insulation layer, a patterned semiconductor active layer, a patterned source and drain metal layer, and a pixel electrode on the base substrate,
wherein the method further comprises: forming an organic transparent insulation layer between the patterned gate metal layer and the pixel electrode,
wherein the patterned gate metal layer comprises a gate and a gate line, and the patterned source and drain metal layer comprises a source and a drain.

12. The method according to claim 11, wherein the forming the organic transparent insulation layer between the patterned gate metal layer and the pixel electrode comprises: forming the organic transparent insulation layer between the patterned source and drain metal layer and the pixel electrode; and the pixel electrode is connected with the drain by a through hole exposing the drain.

13. The method according to claim 11, the method further comprising: forming a passivation layer and a common electrode on the base substrate, the pixel electrode and the common electrode are respectively disposed at two sides of the passivation layer; wherein the pixel electrode is connected with the drain by a through hole exposing the drain.

14. The method according to claim 13, wherein the pixel electrode is formed between the passivation layer and the organic transparent insulation layer, and the common electrode is formed on a side of the passivation layer opposite to the base substrate; or
the common electrode is disposed between the passivation layer and the organic transparent insulation layer, and the pixel electrode is disposed on a side of the passivation layer opposite to the base substrate.

15. The method according to claim 11, wherein the method further comprises: forming an etching blocking layer on a side of the semiconductor active layer opposite to the base substrate, wherein the semiconductor active layer is an oxide semiconductor active layer.

16. The method according to claim 11, wherein a thickness of the organic transparent insulation layer is 2000 Å˜5000 Å.

17. The method according to claim 11, wherein the array substrate is a top-gate type array substrate or a bottom-gate type array substrate.

18. The method according to claim 15, wherein a material of the oxide semiconductor active layer is ZnO, InZnO, ZnSnO, GaInZnO or ZrInZnO.

19. The method according to claim 15, wherein in the case that the array substrate is a bottom-gate type array substrate, the forming the patterned gate metal layer, the gate insulation layer, the patterned semiconductor active layer, the patterned source and drain metal layer and the pixel electrode on the base substrate comprises:
fabricating a metal thin film on the base substrate, and forming the patterned gate metal layer by one patterning process;
fabricating an insulating thin film on the base substrate obtained after the above step, to form the gate insulation layer;
fabricating an oxide semiconductor thin film on the base substrate obtained after the above step, and forming the patterned semiconductor active layer by one patterning process;
fabricating an inorganic thin film on the base substrate obtained after the above step, and forming the etching blocking layer by one patterning process, wherein the etching blocking layer comprises a through hole exposing the drain;
fabricating a metal thin film on the base substrate obtained after the above step, and forming the patterned sourced and drain metal layer by one patterning process;
fabricating an organic transparent insulation thin film on the base substrate obtained after the above step, and forming the organic transparent insulation layer by one patterning process, wherein the organic transparent insulation layer comprises a through hole exposing the drain; and
fabricating a transparent conductive thin film on the base substrate obtained after the above step, and forming the pixel electrode by one patterning process, wherein the pixel electrode is connected with the drain by the through hole exposing the drain.

20. The method according to claim 19, further comprising:
forming a passivation layer on the base substrate obtained after the above steps; and
forming a common electrode on the passivation layer.
